(19) United States
(12) Patent Application Publication
(10) Pub. No.: US 2025/0089333 A1
(43) Pub. Date: Mar. 13, 2025

(54) INNER SPACERS FOR MULTI-GATE TRANSISTORS AND MANUFACTURING METHOD THEREOF

(71) Applicant: Taiwan Semiconductor Manufacturing Company, Ltd., Hsin-Chu (TW)

(72) Inventors: Hung-Ju Chou, Hsinchu (TW); Wei-Yang Lee, Taipei City (TW); Chih-Ching Wang, Kinmen County (TW); Yuan-Ching Peng, Hsinchu (TW)

(21) Appl. No.: 18/512,570

(22) Filed: Nov. 17, 2023

Related U.S. Application Data
(60) Provisional application No. 63/582,085, filed on Sep. 12, 2023.

(51) Int. Cl. H01L 29/66; H01L 29/06; H01L 29/423; H01L 29/775; H01L 29/786

(52) U.S. Cl. CPC H10D 64/018; H10D 30/014; H10D 30/43; H10D 30/6735; H10D 30/6757; H10D 62/121; H10D 64/017

(57) ABSTRACT

The present disclosure provides a semiconductor device and a method of forming the same. A method according one embodiment of the present disclosure include forming an epitaxial stack of channel layers and sacrificial layers on a semiconductor substrate, patterning the epitaxial stack to form a first fin-shape structure in a first region and a second fin-shape structure in a second region, etching the first fin-shape structure to form a first source/drain recess, etching the second fin-shape structure to form a second source/drain recess, forming first inner spacers in the first region, forming second inner spacers in the second region, laterally recessing the second inner spacers, forming a first source/drain feature in the first source/drain recess, and forming a second source/drain feature in the second source/drain recess. After the laterally recessing of the second inner spacers, the second inner spacers have a thickness less than the first inner spacers.

### PRIORITY DATA

This application claims priority to U.S. Provisional Patent Application No. 63/582,085, filed on Sep. 12, 2023, entitled “Inner Spacers For Multi-gate Transistors And Manufacturing Method Thereof”, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Recently, multi-gate transistors have been introduced in an effort to improve gate control by increasing gate-channel coupling, reduce OFF-state current, and reduce short-channel effects (SCEs). One such multi-gate transistor that has been introduced is the fin field-effect transistor (FinFET). The FinFET gets its name from the fin-like structure which extends from a substrate on which it is formed, and which is used to form the FET channel. A further type of multi-gate transistor, introduced in part to address performance challenges associated with some configurations of FinFETs, is the gate-all-around (GAA) transistor. The GAA device gets its name from the gate structure which extends completely around the channel region, providing access to the channel on four sides. GAA devices are compatible with conventional complementary metal-oxide-semiconductor (CMOS) processes and their structure allows them to be aggressively scaled while maintaining gate control and mitigating SCEs. In general, GAA devices may be implemented, for example, in cases where FinFETs can no longer meet performance requirements. However, GAA device fabrication can be challenging, and current methods continue to face challenges with respect to both device fabrication and performance. For example, in a GAA process flow, dimensions of inner spacers can be important for device performance. Yet, in advanced sub-micron nodes, further optimization of performance for n-type transistors and p-type transistors may require different dimensions of inner spacers. Therefore, while the current methods of inner spacer formation in a GAA process flow have been satisfactory in many respects, challenges with respect to performance of the resulting device may not be satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIG. 2A illustrates a perspective view of a workpiece during a fabrication process according to the method of FIG. 1, according to one or more aspects of the present disclosure.

FIG. 2B illustrates a top view of a workpiece during a fabrication process according to the method of FIG. 1, according to one or more aspects of the present disclosure.

FIGS. 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 17A, and 17B illustrate fragmentary cross-sectional views of a workpiece during a fabrication process according to the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure is generally related to multi-gate transistors and fabrication methods, and more particularly to inner spacer formation during fabricating gate-all-around (GAA) transistors.

Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanowire channel(s), bar-shaped channel(s), and/or other suitable channel configurations. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

In a GAA transistor, the gate of the transistor is made all around the channel such that the channel is surrounded or wrapped by the gate. Such a transistor has the advantage of improving the electrostatic control of the channel by the gate, which also mitigates leakage currents. A GAA transistor includes inner spacers and outer gate sidewall spacers (or simply gate spacers, or referred to as gate spacer layer), among others. Inner spacers are typically formed by an additional process to gate spacers. For example, after making gate spacers and epitaxially growing source/drain features, a space for inner spacers is made by removing sacrificial layers that are alternatively arranged with channel layers. Then, inner spacers are formed by dielectric material deposition and removing a portion of the dielectric material from a channel region. Generally, inner spacers at an n-type transistor region (or simply n-type region) and a p-type transistor region (or simply p-type region) are formed simultaneously. As a result, inner spacers at an n-type region and a p-type region typically have similar dimensions. However, further optimization of n-type transistors and p-type transistors may require different inner spacer dimensions. For example, an inner spacer dimension suitable for n-type transistors may adversely impact p-type transistor DC/AC performances, such as ON/OFF current ratio and ring oscillator (RO) performance. One reason is that the inner spacers separate source/drain features from a gate edge and affects an underlapped condition which p-type transistors are more sensitive to. An underlapped condition may be defined as a structure where a source/drain region is spaced away from a gate edge. Source/drain region(s) may refer to a source or a drain, individually or collectively dependent upon the context. The underlapped condition is also referred to as junction underlap. Compared with n-type transistors, a relatively smaller lateral distance between a source/drain feature and a gate edge in p-type transistors may mitigate the negative impact due to junction underlap. An object of the present disclosure is to devise an inner spacer formation method so as to provide different inner spacer dimensions in different regions, particularly relatively thinner inner spacers in a p-type region to improve p-type transistor performance with relatively thicker inner spacers in an n-type region without compromising n-type transistor performance.

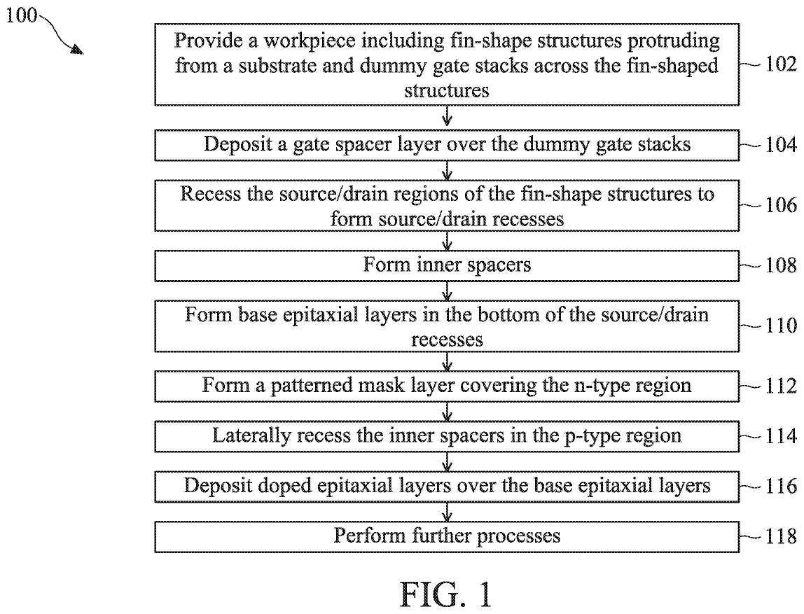

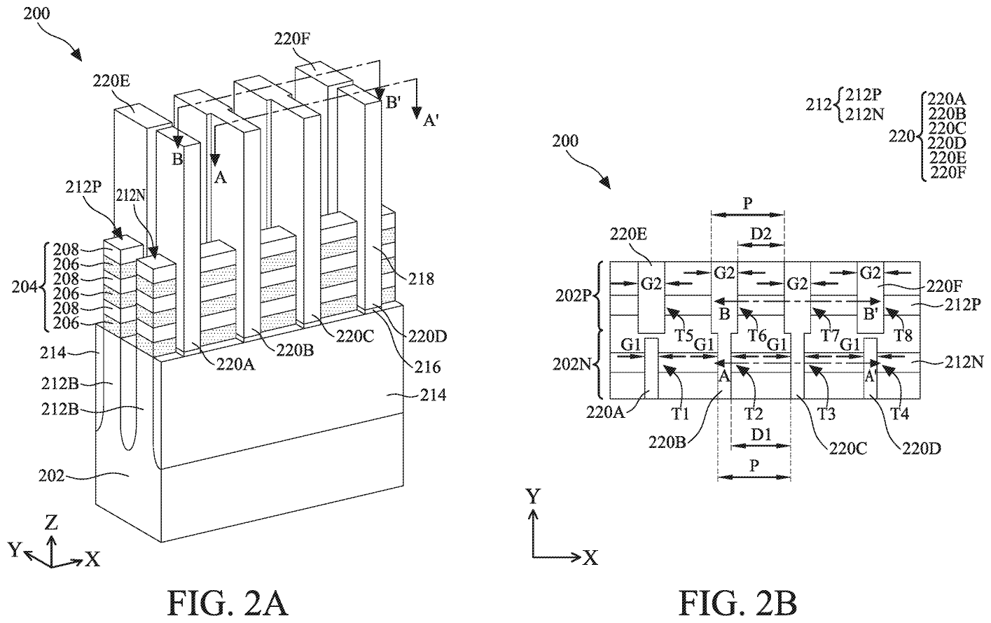

The various aspects of the present disclosure will now be described in more detail with reference to the figures. In that regard, FIG. 1 is a flowchart illustrating a method 100 of forming a semiconductor device from a workpiece according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIGS. 2A-2B, which are a perspective view and a top view of workpiece 200 respectively, and 3A-17B, which are fragmentary cross-sectional views of workpiece 200, at different stages of fabrication according to embodiments of the method 100 in FIG. 1. Because the workpiece 200 will be fabricated into a semiconductor device, the workpiece 200 may be referred to herein as a semiconductor device 200 as the context requires. For avoidance, the X, Y and Z directions in FIGS. 2A-17B are perpendicular to one another. Throughout the present disclosure, like reference numerals denote like features, unless otherwise excepted.

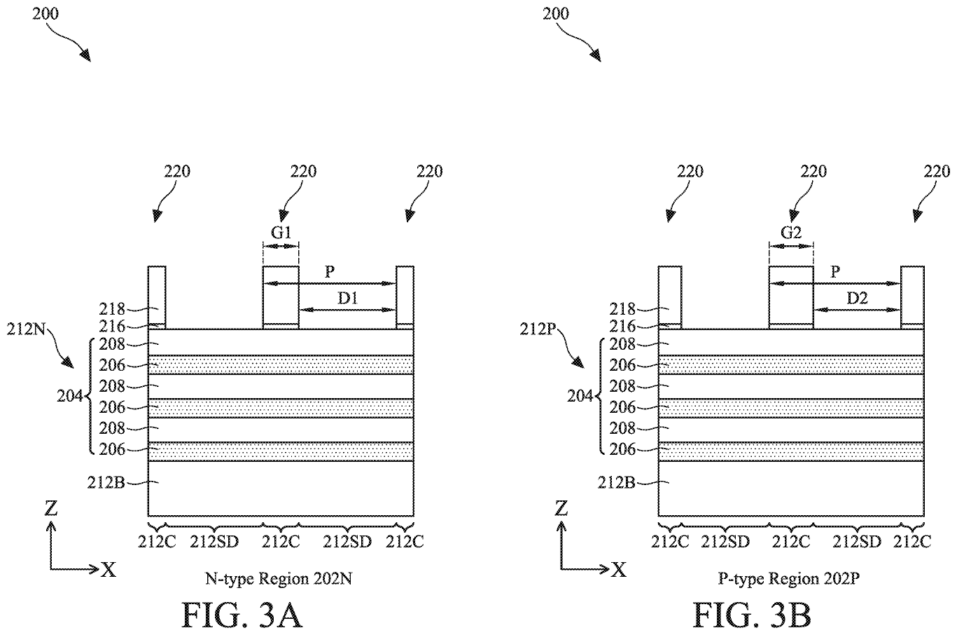

Referring to FIGS. 1, 2A-2B, and 3A-3B, method 100 includes a block 102 where a workpiece 200 is provided with multiple fin-shape structures 212 (e.g., fin-shape structures 212N, 212P) protruding from a substrate 202 and oriented lengthwise along the X direction, and multiple dummy gate stacks 220 (e.g., dummy gate stacks 220A-F) across the fin-shape structures 212 and oriented lengthwise along the Y direction. FIG. 3A is a cross-sectional view cut through A-A′ line in FIGS. 2A and 2B, which cuts in the lengthwise direction of a fin-shape structure 212N. The fin-shape structure 212N is in an n-type region 202N where n-type transistors will be formed. FIG. 3B is a cross-sectional view cut through B-B′ line in FIGS. 2A and 2B, which cuts in the lengthwise direction of a fin-shape structure 212P. The fin-shape structure 212P is in a p-type region 202P where p-type transistors will be formed.

In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the portion of the substrate 202 in the p-type region 202P. In some implementations, the n-type dopant for forming the n-type well may include phosphorus (P) or arsenide (As). In embodiments where the semiconductor device is n-type, a p-type doping profile (i.e., a p-type well or p-well) may be formed on the portion of the substrate 202 in the n-type region 202N. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

Each fin-shape structure 212 includes a stack 204 of alternating semiconductor layers atop a fin-shape base 212B. The formation of the fin-shape structures 212 may include depositing the stack 204 on the substrate 202 in an epitaxial growth process and patterning the stack 204 and a top portion of the substrate 202 to form the fin-shape structures 212. Since the fin-shape base 212B is formed by patterning a top portion of the substrate 202, the fin-shape base 212B may still be considered as a top part of the substrate 202 as the context requires.

The stack 204 includes sacrificial layers 206 of a first semiconductor composition interleaved by channel layers 208 of a second semiconductor composition. The first and second semiconductor composition may be different. In some embodiments, the sacrificial layers 206 include silicon germanium (SiGe) and the channel layers 208 include silicon (Si). It is noted that three (3) layers of the sacrificial layers 206 and three (3) layers of the channel layers 208 are alternately arranged in the depicted embodiment, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 1 and 20.

In some embodiments, all sacrificial layers 206 may have a substantially uniform first thickness between about 3 nm and about 10 nm and all of the channel layers 208 may have a substantially uniform second thickness between about 3 nm and about 15 nm. The first thickness and the second thickness may be the same or different. As described in more detail below, the channel layers 208 or parts thereof may serve as channel member(s) for a subsequently-formed multi-gate device and the thickness of each of the channel layers 208 is chosen based on device performance considerations. The sacrificial layers 206 in channel regions(s) may eventually be removed and serve to define a vertical distance between adjacent channel region(s) for a subsequently-formed multi-gate device and the thickness of each of the sacrificial layers 206 is chosen based on device performance considerations.

The layers in the stack 204 may be deposited using a molecular beam epitaxy (MBE) process, a vapor phase deposition (VPE) process, and/or other suitable epitaxial growth processes. Therefore, the stack 204 is also referred to as the epitaxial stack 204. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 cm⁻³ to about 1×10¹⁷ cm⁻³), where for example, no intentional doping is performed during the epitaxial growth processes for the stack 204.

In some embodiments, the fin-shape structures 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. In some implementations, double-patterning or multi-patterning processes may be used to define fin-shape structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shape structures 212 by etching the stack 204 and a top portion of the substrate 202. In some instances, each fin-shape structure 212 measures between about 6 nm and about 80 nm wide along the Y direction, and a distance between opposing sidewalls of two adjacent fin-shape structures 212 measures between about 10 nm and about 115 nm along the Y direction.

The workpiece 200 includes an isolation feature 214 deposited in trenches between opposing sidewalls of two adjacent fin-shape structures 212. In some embodiments, the isolation feature 214 may be formed in the trenches to isolate the fin-shape structures 212 from a neighboring fin-shape structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214. The fin-shape structures 212 rise above the STI feature 214 after the recessing. The recessed top surface of the STI feature 214 may be leveled with a top surface of the fin-shaped base 212B.

The formation of the dummy gate stacks 220 may include deposition of layers in the dummy gate stack 220 and patterning of these layers. A dummy dielectric layer 216, a dummy electrode layer 218, and a gate-top hard mask layer (not shown) may be blanketly deposited over the workpiece 200. In some embodiments, the dummy dielectric layer 216 may be formed on the fin-shape structure 212 using a chemical vapor deposition (CVD) process, an ALD process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer may be deposited on the dummy electrode layer 218 using a CVD process, an ALD process, or other suitable processes. The dummy electrode layer 218 and the dummy dielectric layer 216 may then be patterned to form the dummy gate stacks 220 using the gate-top hard mask layer as a patterning mask. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods.

The dummy gate stacks 220 are formed over respective channel regions of the fin-shape structures 212. In some embodiments, a gate replacement process (or gate-last process) is adopted where the dummy gate stacks 220 serve as a placeholder to undergo various processes and are to be removed and replaced by the functional gate structures. At intersections of the fin-shape structures 212 and the functional gate structures, transistors are formed, such as transistors T1-T8 as illustrated in FIG. 2B. In the depicted embodiment, with the dummy gate stacks 220 formed over the fin-shape structures 212, the fin-shape structures 212 are divided into channel regions 212C underlying the dummy gate stacks 220 and source/drain regions 212SD that do not underlie the dummy gate stacks 220. The channel regions 212C are adjacent the source/drain regions 212SD. As shown in FIGS. 3A and 3B, each channel region 212C is disposed between two source/drain regions 212SD along the X direction.

Transistors T1-T8 as illustrated in FIG. 2B may form a portion of a functional circuit. In one non-limiting implementation, transistors T1-T8 form an SRAM cell, such as a two-port SRAM cell. In an exemplary two-port SRAM cell, the transistor T1 to be formed at the intersection of the fin-shape structure 212N and the dummy gate stack 220A is an n-type transistor and may function as a first pass-gate transistor (PG-1) in the write-port of the SRAM cell. The transistor T2 to be formed at the intersection of the fin-shape structure 212N and the dummy gate stack 220B is an n-type transistor and may function as a first pull-down transistor (PD-1) in the write-port of the SRAM cell. The transistor T3 to be formed at the intersection of the fin-shape structure 212N and the dummy gate stack 220C is an n-type transistor and may function as a second pull-down transistor (PD-2) in the write-port of the SRAM cell. The transistor T4 to be formed at the intersection of the fin-shape structure 212N and the dummy gate stack 220D is an n-type transistor and may function as a second pass-gate transistor (PG-2) in the write-port of the SRAM cell. The transistor T5 to be formed at the intersection of the fin-shape structure 212P and the dummy gate stack 220E is a p-type transistor and may function as a pass-gate transistor (PG-R1) in the first read-port of the SRAM cell. The transistor T6 to be formed at the intersection of the fin-shape structure 212P and the dummy gate stack 220B is a p-type transistor and may function as a first pull-up transistor (PU-1) in the write-port of the SRAM cell. The transistor T7 to be formed at the intersection of the fin-shape structure 212P and the dummy gate stack 220C is a p-type transistor and may function as a second pull-up transistor (PU-2) in the write-port of the SRAM cell. The transistor T8 to be formed at the intersection of the fin-shape structure 212P and the dummy gate stack 220F is a p-type transistor and may function as a pass-gate transistor (PG-R2) in the second read-port of the SRAM cell.

Further, as suggested in the depicted embodiment as shown in FIG. 2B, after the gate replacement process, the functional gate structure replacing the dummy gate stack 220B would extend into both the n-type region 202N and the p-type region 202P, such that the transistors T2 and T6 share the same gate structure. Similarly, the functional gate structure replacing the dummy gate stack 220C would extend into both the n-type region 202N and the p-type region 202P, such that the transistors T3 and T7 share the same gate structure. As a comparison, the functional gate structure replacing the dummy gate stack 220A would be spaced apart from the function gate structure replacing the dummy gate stack 220E by a gate isolation feature (also referred to as a gate-cut feature, or a cut-metal-gate feature), and the functional gate structure replacing the dummy gate stack 220D would be spaced apart from the function gate structure replacing the dummy gate stack 220F by another gate isolation feature.

Still further, in the depicted embodiment as shown in FIG. 2B, the dummy gate stacks in the n-type region 202N and the p-type region 202P may have the same pitch but different gate widths (also referred to as gate CD). For example, the portions of dummy gate stacks 220 in the n-type region 202N may have a uniform gate width (also referred to as gate CD) G1, and the portions of dummy gate stacks 220 in the p-type region 202P may have a uniform gate width G2 that is larger than G1. In some embodiments, the gate width G1 measures in a range between about 9 nm and 11 nm along the X direction, and the gate width G2 measures in a range between about 12 nm and about 14 nm along the X direction. The larger gate width G2 of the p-type type region 202P improves gate control in the p-type transistors and compensates the relatively low mobility of carrier holes in the p-type transistors. With the same gate pitch P in the n-type region 202N and the p-type region 202P, the larger gate width G2 also translates to a smaller gate spacing D2 between opposing sidewalls of two adjacent dummy gate stacks in the p-type region 202P compared to a larger gate spacing D1 in the n-type region 202N. In other words, the source/drain regions 212SD in the p-type region 202P are narrower than the source/drain regions 212SD in the n-type region 202N along the X direction, and the channel regions 212C in the p-type region 202P are longer than the channel regions 212C in the n-type region 202N.

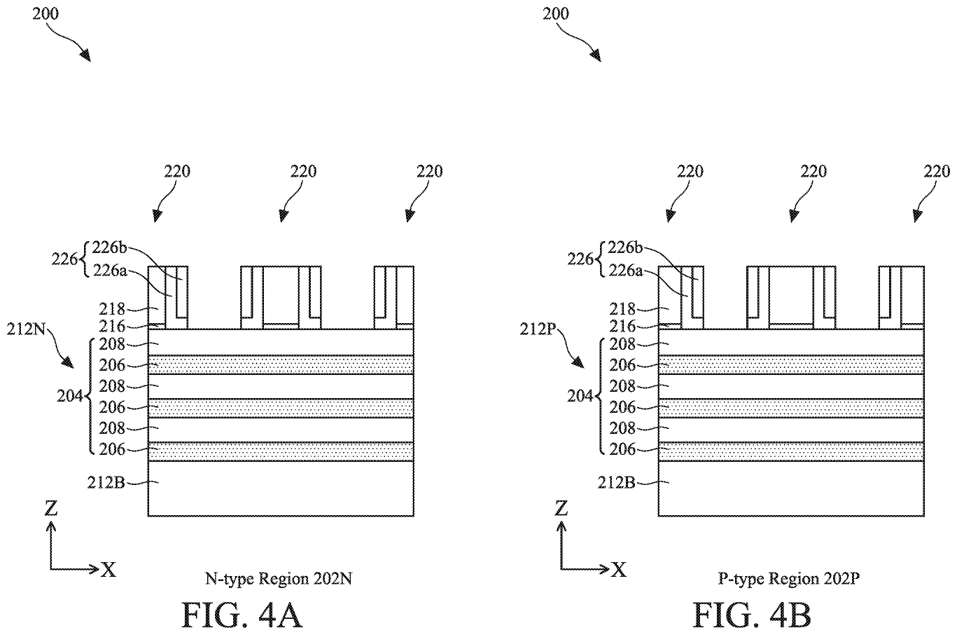

Referring to FIGS. 1 and 4A-4B, method 100 includes a block 104 where a gate spacer layer 226 is deposited over the dummy gate stack 220. In some embodiments, the gate spacer layer 226 is deposited conformally over the workpiece 200, including over top surface and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process. In the depicted embodiment, the gate spacer layer 226 includes a first layer 226a and a second layer 226b disposed over the first layer 226a. The first layer 226a may include silicon oxynitride and the second layer may include silicon nitride. In some embodiments, the gate spacer layer 226 measures between about 5 nm and about 15 nm thick along the X direction. The gate spacer layer 226 may also be referred to as gate spacers 226.

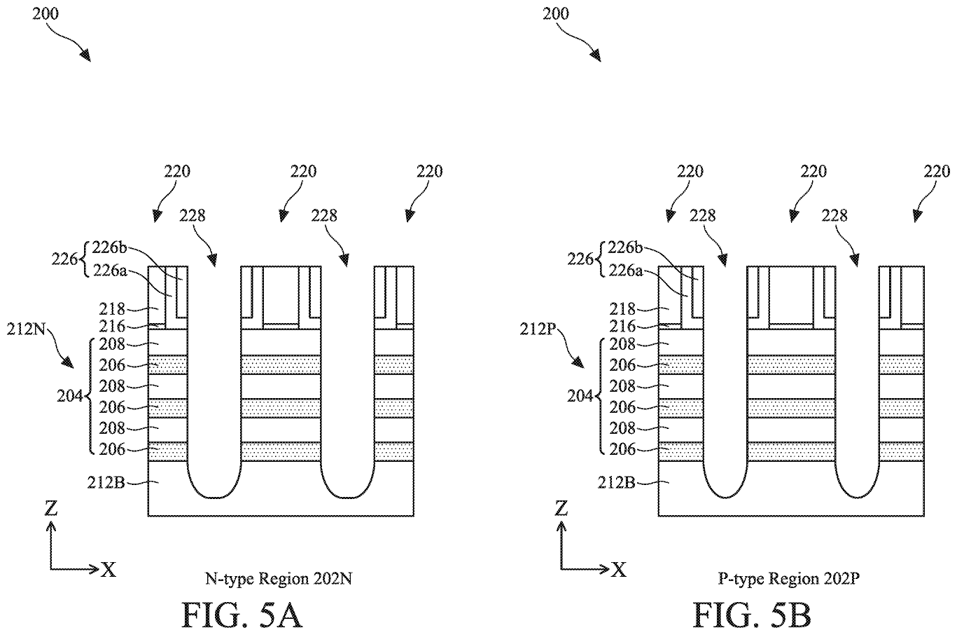

Referring to FIGS. 1 and 5A-5B, method 100 includes a block 106 where source/drain regions 212SD of the fin-shape structures 212 are recessed to form source/drain trenches 228. In some embodiments, the source/drain regions 212SD that are not covered by the dummy gate stack 220 and the gate spacer layer 226 are etched by a dry etch or a suitable etching process to form the source/drain trenches 228. For example, the dry etch process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. In some embodiments, the source/drain regions 212SD of the fin-shape structures 212 are recessed to expose sidewalls of the sacrificial layers 206 and the channel layers 208. In some implementations, the source/drain trenches 228 extend below the stack 204 into the fin-shaped base 212B.

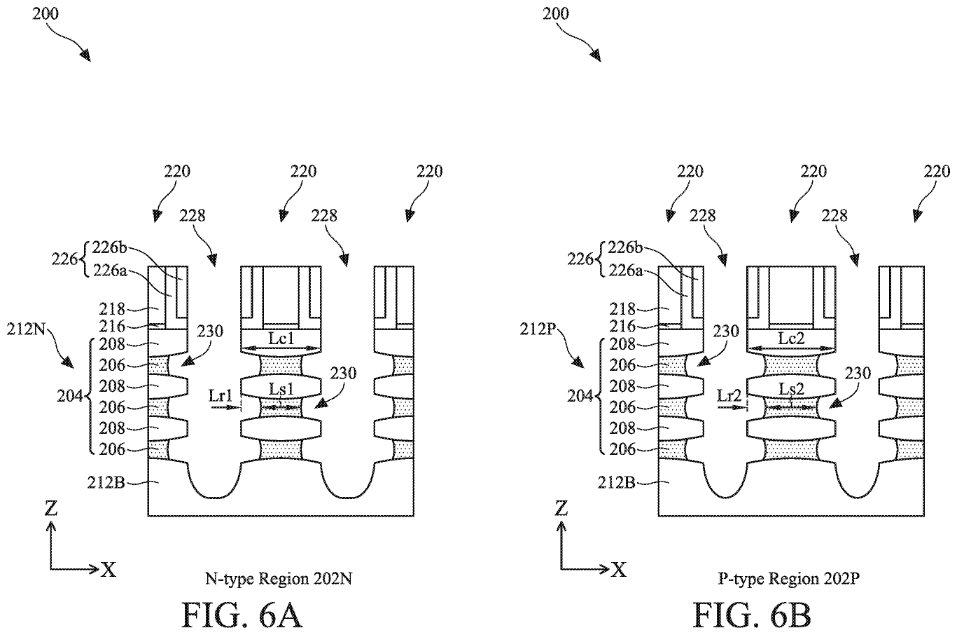

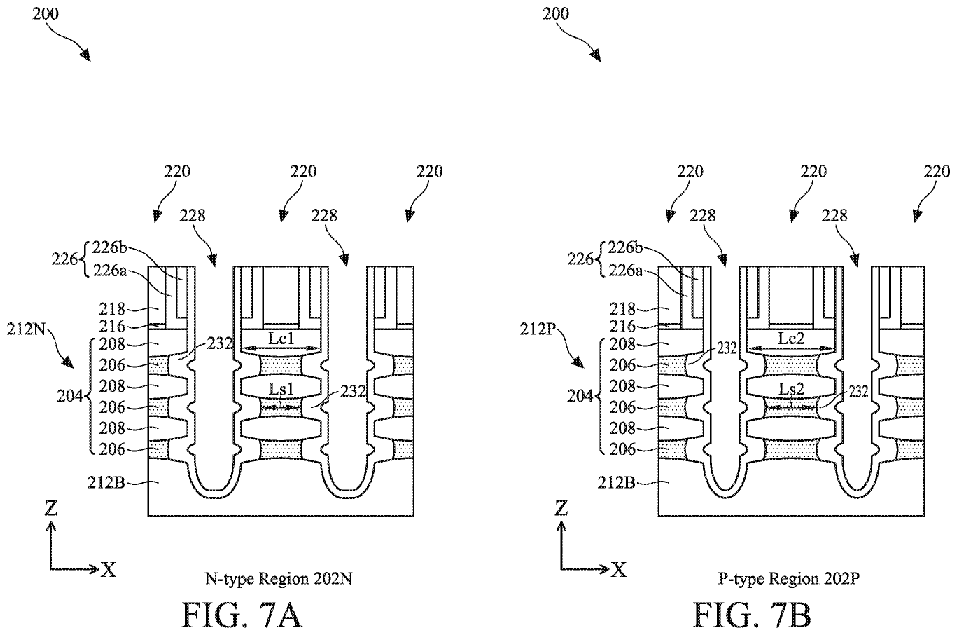

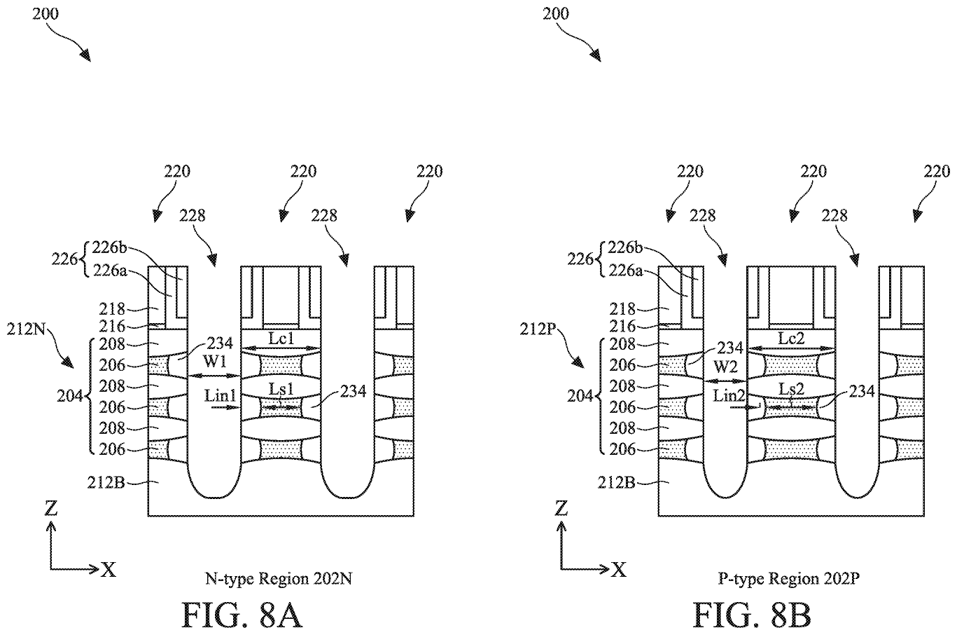

Referring to FIGS. 1, 6A-6B, 7A-7B, and 8A-8B, method 100 includes a block 108 where inner spacers 234 are formed. Operation at block 108 may include selective and partial removal of the sacrificial layers 206 to form inner spacer recesses 230 (shown in FIGS. 6A-6B), deposition of inner spacer material 232 over the workpiece 200 (shown in FIGS. 7A-7B), and etch back the inner spacer material 232 to form inner spacers 234 in the inner spacer recesses 230 (shown in FIGS. 8A-8B). Referring to FIGS. 6A-6B, the sacrificial layers 206 exposed in the source/drain trenches 228 are selectively and partially recessed to form inner spacer recesses 230 while the gate spacer layer 226, the exposed portion of the fin-shape base 212B (the substrate 202), and the channel layers 208 are substantially unetched. In an embodiment where the channel layers 208 consist essentially of silicon (Si) and sacrificial layers 206 consist essentially of silicon germanium (SiGe), the selective recess of the sacrificial layers 206 may be performed using a selective wet etch process or a selective dry etch process. The selective and partial recess of the sacrificial layers 206 may include a SiGe oxidation process followed by a SiGe oxide removal. In that embodiment, the SiGe oxidation process may include use of ozone. In some other embodiments, the selective dry etching process may include use of one or more fluorine-based etchants, such as fluorine gas or hydrofluorocarbons. The selective wet etching process may include an APM etch (e.g., ammonia hydroxide-hydrogen peroxide-water mixture).

Due to the smaller gate width in the n-type region 202N than in the p-type region 202P and the substantially same thickness of the gate spacer layer 226 in both the n-type region 202N and the p-type region 202P, the length of the channel layers 208 in the n-type region 202N (denoted as Lc1) may be smaller than the length of the channel layers 208 in the p-type region 202P (denoted as Lc2). In some embodiments, the channel length Lc1 in the n-type region 202N is in a range between about 29 nm and about 31 nm, and the channel length Lc2 in the p-type region 202P is in a range between about 32 nm to about 34 nm. As a comparison, the length of the sacrificial layers 206 in the n-type region 202N (denoted as Ls1) and the length of the sacrificial layers 206 in the p-type region 202P (denoted as Ls2) may substantially be the same. In some embodiments, the sacrificial layer lengths Ls1 and Ls2 each are in a range between about 12 nm and about 14 nm. The similar length of the sacrificial layers 206 in both the n-type region 202N and the p-type region 202P may be due to a larger lateral etching rate and the resultant larger lateral recessed distance of the sacrificial layers 206 along the X-direction in the p-type region 202P. In other words, the length of the inner spacer recesses 230 in the n-type region 202N (denoted as Lr1) may be smaller than the length of the inner spacer recesses 230 in the p-type region 202P (denoted as Lr2). In some alternative embodiments, the lengths Lr1 and Lr2 of the inner spacer recesses 230 may substantially be the same, and the sacrificial layer length Ls1 in the n-type region 202N is smaller than the sacrificial layer length Ls2 in the p-type region 202P.

Referring to FIGS. 7A-7B, after the inner spacer recesses 230 are formed, the inner spacer material 232 is deposited over the workpiece 200, including over the inner spacer recesses 230. The inner spacer material 232 may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material 232 may be a single layer or a multilayer. In some implementations, the inner spacer material 232 may be deposited using CVD, PECVD, SACVD, ALD or other suitable methods. The inner spacer material 232 is deposited into the inner spacer recesses 230 as well as over the sidewalls of the channel layers 208 exposed in the source/drain trenches 228.

Referring to FIGS. 8A-8B, the deposited inner spacer material 232 is then etched back to remove the inner spacer material 232 from the sidewalls of the channel layers 208 to form the inner spacers 234 in the inner spacer recesses 230. The inner spacer material 232 may also be removed from sidewalls of the gate spacers 226. In some implementations, the etch back operations performed at block 112 may include use of hydrogen fluoride (HF), fluorine gas (F₂), hydrogen (H₂), ammonia (NH₃), nitrogen trifluoride (NF₃), or other fluorine-based etchants. Each of the inner spacers 234 is in direct contact with the recessed sacrificial layers 206 and is disposed between two neighboring channel layers 208. In the depicted embodiment, each of the inner spacers 234 has a straight sidewall that is flushed with sidewalls of the gate spacers 226. Alternatively, the sidewalls of the inner spacers 234 may be concave (i.e., bending inward towards the respective sacrificial layer 206) or convex (i.e., bending outward towards the respective source/drain trench 228). Measured between opposing sidewalls of the inner spacers 234 along the X direction, the source/drain trenches 228 in the n-type region 202N have a width W1 larger than a width W2 of the source/drain trenches 228 in the p-type region 202P. As discussed above, the length of the inner spacer recesses 230 in the n-type region 202N may be smaller than the length of the inner spacer recesses 230 in the p-type region 202P, and consequently the length of the inner spacers 234 in the n-type region 202N (denoted as Lin1) may be smaller than the length of the inner spacers 234 in the p-type region 202P (denoted as Lin2) along the X direction. In some instances, the inner spacer length Lin1 in the n-type region 202N measures between about 7.5 nm and about 8.5 nm, and the inner spacer length Lin2 in the p-type region 202P measures between about 9 nm to about 10 nm. In some alternative embodiments, the inner spacer lengths Lin1 and Lin2 may substantially be the same, such as both in a range between about 7.5 nm and about 8.5 nm.

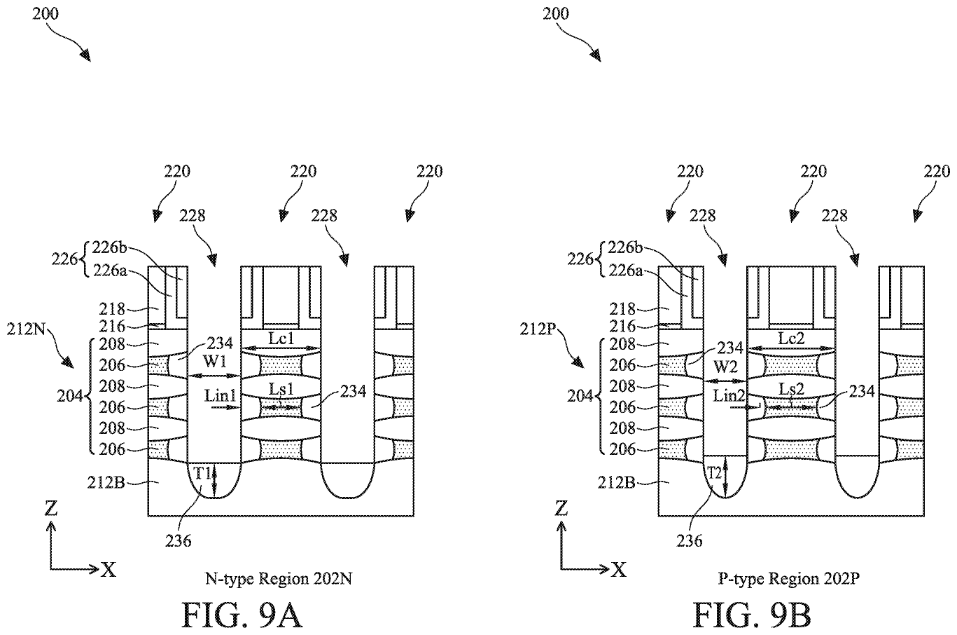

Referring to FIGS. 1 and 9A-9B, method 100 includes a block 110 where base epitaxial layers 236 are deposited in the bottom of the source/drain trenches 228 in both the n-type region 202N and the p-type region 202P. In some embodiments, the base epitaxial layer 236 includes the same material as the substrate 202 and the channel layers 208, such as silicon (Si), except for a dopant condition (doping element and/or doping concentration). For example, the base epitaxial layer 236 is made of non-doped silicon, the substrate 202 is made of doped silicon, and the channel layers 208 are made of non-doped or doped silicon. In some embodiments, the base epitaxial layer 236 includes the same material as the sacrificial layers 206, such as silicon germanium (SiGe), but with different germanium (Ge) contents. In other embodiments, the base epitaxial layer 236, the channel layers 208, and the sacrificial layers 206 are made of semiconductor materials different from each other. In various embodiments, the base epitaxial layer 236 is dopant-free, where for example, no intentional doping is performed during the epitaxial growth process. As a comparison, the substrate 202 may be lightly doped and has a higher doping concentration than the base epitaxial layer 236. The base epitaxial layer 236 provides a high resistance path from the source/drain regions to the semiconductor substrate, such that the leakage current in the semiconductor substrate (i.e., through the fin-shaped base 212B) is suppressed. The inner spacers 234 limit the vertical growth of the base epitaxial layer 236, as the epitaxial growth may not take place from a dielectric surface. The base epitaxial layer 236 may exhibit faceted growth when it reaches the bottommost inner spacers 234. Thus, in some embodiments, the base epitaxial layer 236 may partially overlap with a bottom portion of the bottommost inner spacers 234 but do not grow vertically beyond a top surface of the bottommost inner spacers 234 (also a bottom surface of the bottommost channel layer 208).

Suitable epitaxial processes for block 110 include vapor-phase epitaxy (VPE), molecular beam epitaxy (MBE), selective CVD, and/or other suitable processes. Various deposition parameters can be tuned to selectively deposit the semiconductor material on exposed semiconductor surfaces in the source/drain trenches 228, such as deposition gas composition, carrier gas composition, deposition gas flow rate, carrier gas flow rate, deposition time, deposition pressure, deposition temperature, source power, RF bias voltage, DC bias voltage, RF bias power, DC bias power, other suitable deposition parameters, or combinations thereof. In some embodiments, the workpiece 200 is exposed to a deposition mixture that includes DCS and/or SiH₄ (silicon-containing precursor), H₂ (carrier precursor), and HCl (etchant-containing precursor) when forming the base epitaxial layer 236. In some embodiments, the selective CVD process implements a deposition temperature of about 600° C. to about 750° C. In some embodiments, the selective CVD process implements a deposition pressure of about 10 Torr to about 100 Torr. In some embodiments, the selective CVD process is configured as a bottom-up deposition process, such that base epitaxial layer 236 grows from the exposed semiconductor surface at the bottom of the source/drain trenches 228, but not from exposed end portions of the channel layers 208. In some embodiments, a post-deposition etch is performed after the selective CVD process to remove semiconductor material of the base epitaxial layer 236 that may remain on end portions of the channel layers 208 if any. The post-deposition etch includes a dry etching, a wet etching, other suitable etching process, or combinations thereof.

Due to the different profiles of the source/drain trenches 228 in the n-type region 202N and the p-type region 202P, the base epitaxial layers 236 have different profiles and volumes in the two regions. For example, due to the narrower opening of the source/drain trench 228 in the p-type region 202P, the epitaxial growth rate in the Z direction in the p-type region 202P may be larger than in the n-type region 202N. As a result, the thickness T1 of the base epitaxial layer 236 in the n-type region 202N may be smaller than the thickness T2 of the base epitaxial layer 236 in the p-type region 202P, and a top surface of the base epitaxial layer 236 in the n-type region 202N may be lower than a top surface of the base epitaxial layer 236 in the p-type region 202P. Even the thickness T1 of the base epitaxial layer 236 in the n-type region 202N may be smaller than the thickness T2 of the base epitaxial layer 236 in the p-type region 202P, due to the larger opening of the source/drain trench 228 in the n-type region 202N, the volume of the base epitaxial layer 236 in the n-type region 202N may still be larger than the volume of the base epitaxial layer 236 in the p-type region 202P.

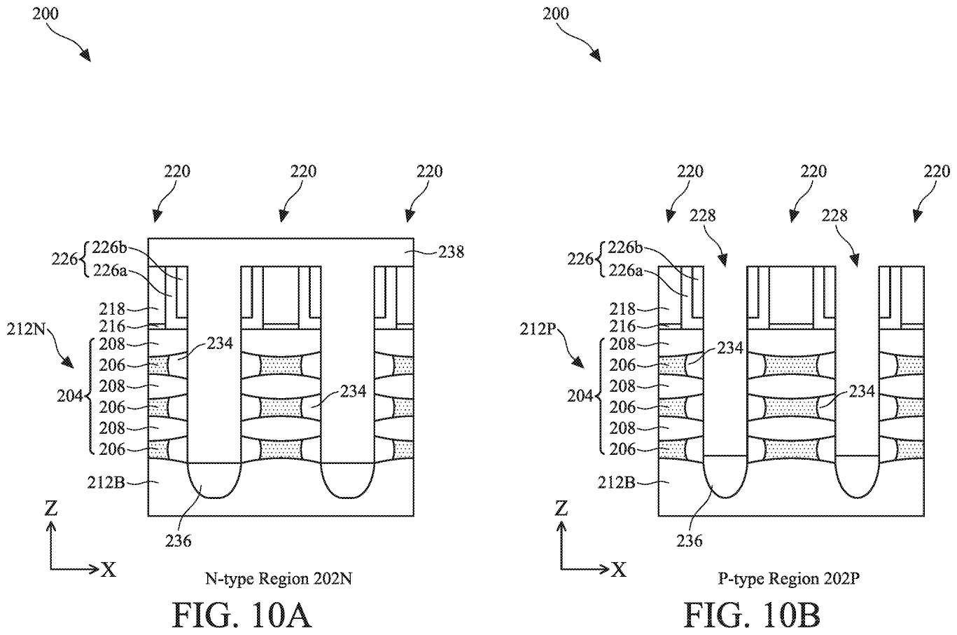

Referring to FIGS. 1 and 10A-10B, method 100 includes a block 112 where a patterned mask layer 238 covering the n-type region 202N is formed. The patterned mask layer 238 covers the n-type region 202N with an opening exposing the p-type region 202P. In some embodiments, the patterned mask layer 238 is a hard mask layer comprising a single layer or a multi-layer. For example, the hard mask layer may include a silicon oxide layer and a silicon nitride layer over the silicon oxide layer. In some other examples, the patterned mask layer 238 may include a metal oxide or a metal nitride, such as La₂O₃, Al₂O₃, ZnO, ZrN, Zr₂Al₃O₉, TiO₂, TaO₂, ZrO₂, HfO₂, Y₂O₃, AlON, TaCN, or combinations thereof. The hard mask layer may be formed using chemical vapor deposition (CVD), low-pressure CVD (LPCVD), plasma-enhanced CVD (PECVD), physical vapor deposition (PVD), atomic layer deposition (ALD), thermal oxidation, electron-beam (e-beam) evaporation, or other suitable deposition techniques, or combinations thereof. The hard mask layer is patterned using any suitable methods such as a photolithography process, which may include forming a resist layer on the hard mask layer, exposing the resist by a lithography exposure process, performing a post-exposure bake process, developing the photoresist layer to form the patterned photoresist layer that exposes part of the hard mask layer, patterning the hard mask layer, and finally removing the patterned resist layer. The lithography process may be alternatively replaced by other suitable techniques, such as e-beam writing, ion-beam writing, maskless patterning or molecular printing.

In some embodiments, the patterned mask layer 238 is a resist layer, such as a tri-layer resist layer that includes a bottom layer, a middle layer, and a top photoresist layer. In furtherance of embodiments, the bottom layer may include a carbon rich polymer material (e.g., CxHyOz), the middle layer may include a silicon rich polymer material (e.g., SiCxHyOz), and the top photoresist layer may include a carbon rich polymer material (e.g., CxHyOz) with a photosensitive component that undergoes a property change when exposed to radiation. The patterning of the top photoresist layer may be achieved, for example, by using an immersion photolithography system to expose portions of the top photoresist layer and developing the exposed or unexposed portions depending on whether a positive or negative photoresist is used. The middle layer is then etched through the openings in the top photoresist layer. In this manner, the top photoresist layer serves as an etch mask limiting the etching process in the p-type region 202P. The bottom layer is subsequently etched through the openings in the top photoresist layer and the middle layer. In this manner, the top photoresist layer and the middle layer collectively serve as an etch mask limiting the etching process in the p-type region 202P.

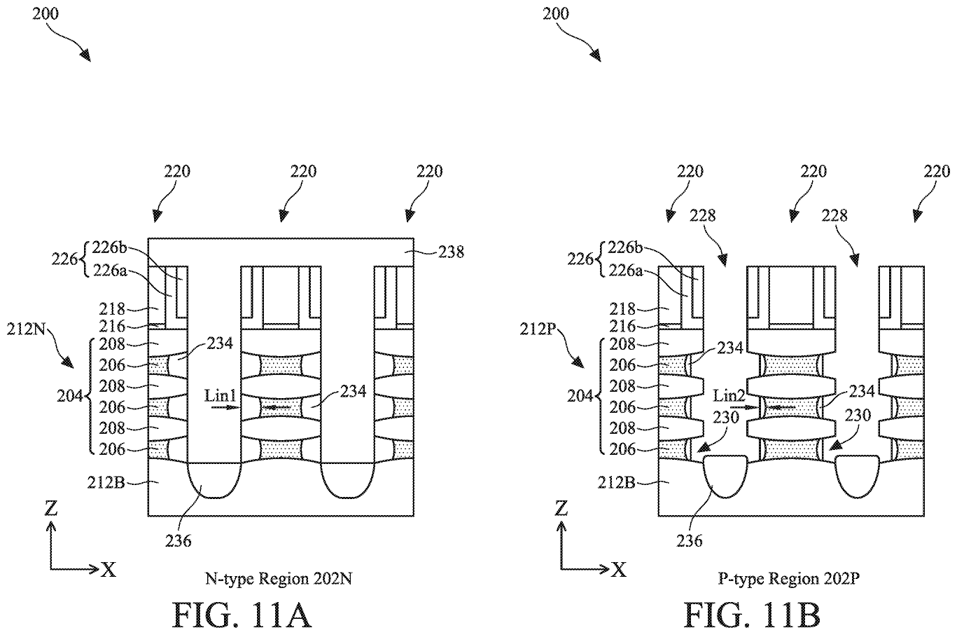

Referring to FIGS. 1 and 11A-11B, method 100 includes a block 114 where the inner spacers 234 in the p-type region 202P are further recessed along the X direction. In some embodiments, the recessing process may include a dry etching process, a wet etching process, and/or a combination thereof. In some embodiments, a lateral recessing depth is controlled (e.g., by controlling an etching time) so as to thin down the inner spacers 234 in the p-type region 202P to partially expose the inner spacer recesses 230 again. In some implementations, the recessing process performed at block 114 is a dry etching process using fluorine-based etchants, such as hydrogen fluoride (HF), fluorine gas (F₂), hydrogen (H₂), ammonia (NH₃), nitrogen trifluoride (NF₃), CH₃F, or other suitable etchants. In one example, the recessing process includes applying an etchant (e.g., a mixture of CH₃F, O₂, and Ar) with a pressure from about 3 mTorr to about 20 mTorr and a bias power from about 500 W to about 1500 W for a duration from about 10 s to about 30 s. In some implementations, the recessing process is a wet etching process using H₃PO₄ or other suitable etchants. After the recessing process, the inner spacer length Lin2 in the p-type region 202P is reduced to a range between about 3 nm to about 6 nm, in some embodiments. This range is not trivial. If the inner spacer length Lin2 is less than about 3 nm, the inner spacers in the p-type region 202P may be too thin and risk breaking through in subsequent processes; if the inner spacer length Lin2 is larger than about 6 nm, the inner spacers in the p-type region 202P may be too thick to effectively mitigate junction underlap in the p-type region 202P. The thinned inner spacers 234 in the p-type region 202P may have a uniform inner spacer length Lin2. Alternatively, from top to bottom, the thinned inner spacers 234 in the p-type region 202P may have a gradually increasing inner spacer length Lin2, which may be due to etching loading effect at different depths of the source/drain trench 228. That is, in the depicted embodiment, the middle inner spacer 234 may be thicker along the X direction than the topmost inner spacer 234, and the bottommost inner spacer 234 may be thicker along the X direction than the middle inner spacer 234. After the recessing process, the inner spacer length Lin1 in the n-type region 202N may be larger than any inner spacer length Lin2 in the p-type region 202P. At the conclusion of block 114, the patterned mask layer 238 is removed from the n-type region 202N in an etching process, an ashing process, or other suitable removal processes.

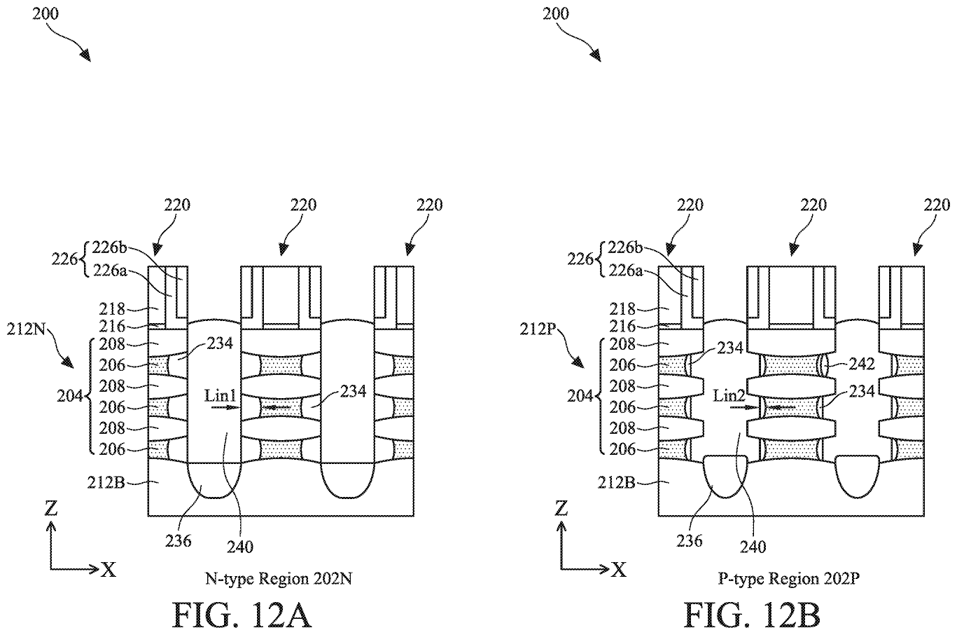

Referring to FIGS. 1 and 12A-12B, method 100 includes a block 116 where doped epitaxial layers 240 are formed in the source/drain trenches 228 in the n-type region 202N and the p-type region 202P. The doped epitaxial layers 240 may also be referred to as source/drain features. Sometimes, the term “source/drain features” includes the doped epitaxial layer 240 and the base epitaxial layer 236 underneath. In an embodiment, forming the doped epitaxial layers 240 includes epitaxially growing the semiconductor layers by an MBE process, a chemical vapor deposition process, and/or other suitable epitaxial growth processes. The doped epitaxial layer 240 in the n-type region 202N may include silicon doped with phosphorous or arsenic for n-type transistors. The doped epitaxial layer 240 in the p-type region 202P may include silicon germanium doped with boron for p-type transistors. In each region, the doped epitaxial layer 240 covers the base epitaxial layer 236 and is in contact with the inner spacers 224. In the p-type region 202P, the doped epitaxial layer 240 also extends into the inner spacer recesses 230, such that the extending portions of the doped epitaxial layer 240 interleave the end portions of the adjacent channel layers 208. That is, in the depicted embodiment, the doped epitaxial layer 240 in the p-type region 202P is in contact with the vertical sidewalls as well as top and bottom surfaces of the end portions of the channel layers 208, while the doped epitaxial layer 240 in the n-type region 202N may be in contact with the vertical sidewalls of the channel layers 208 but not top and bottom surfaces thereof. In some embodiments, a void 242 (also referred to as air pocket) may remain laterally between the thinned inner spacers 234 and the extending portions of the doped epitaxial layer 240 in the p-type region 202P. With the extending portions, a volume of the doped epitaxial layer 240 in the p-type region 202P may be larger than a volume of the doped epitaxial layer 240 in the n-type region 202N, in some embodiments.

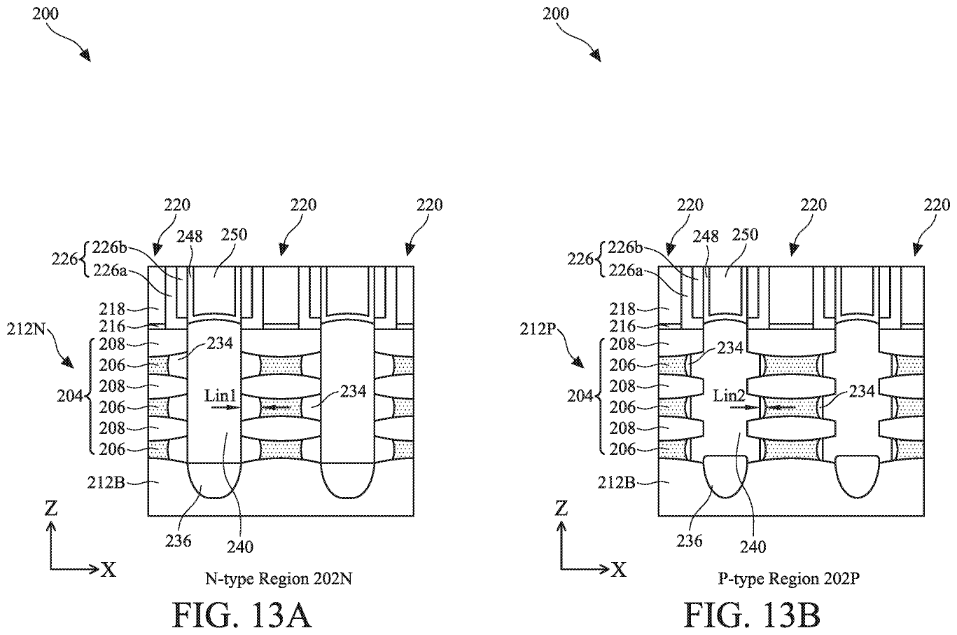

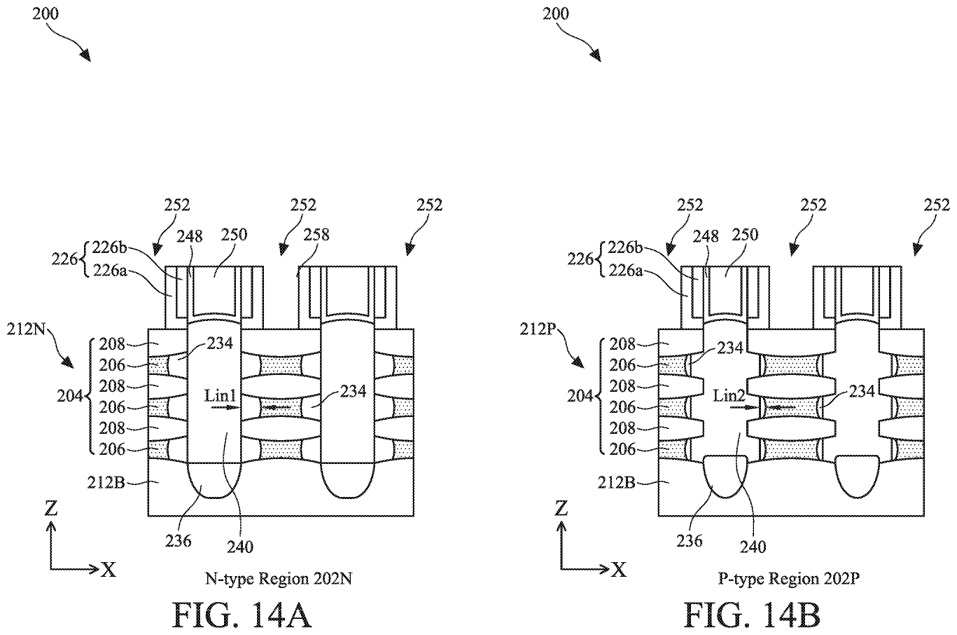

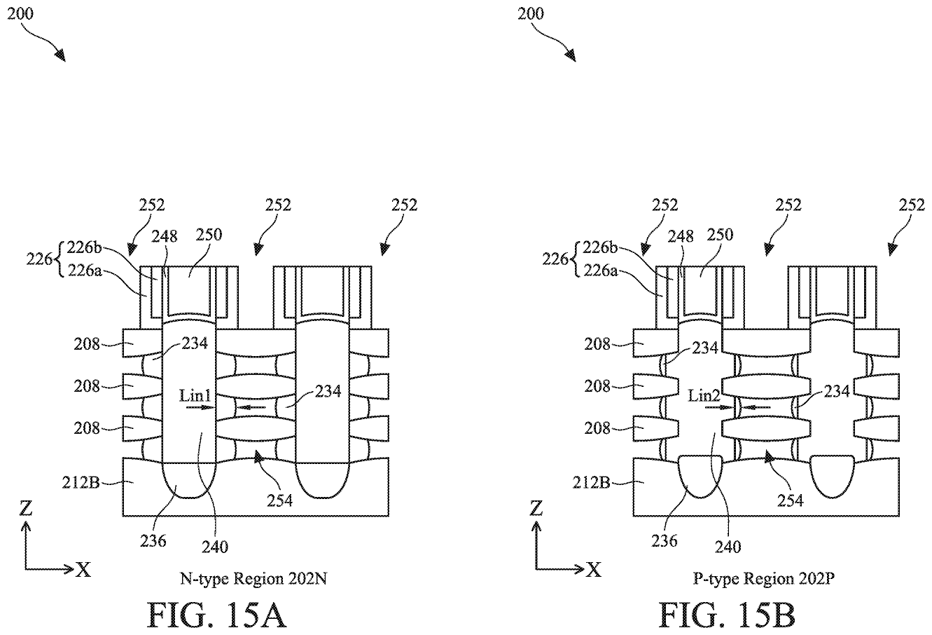

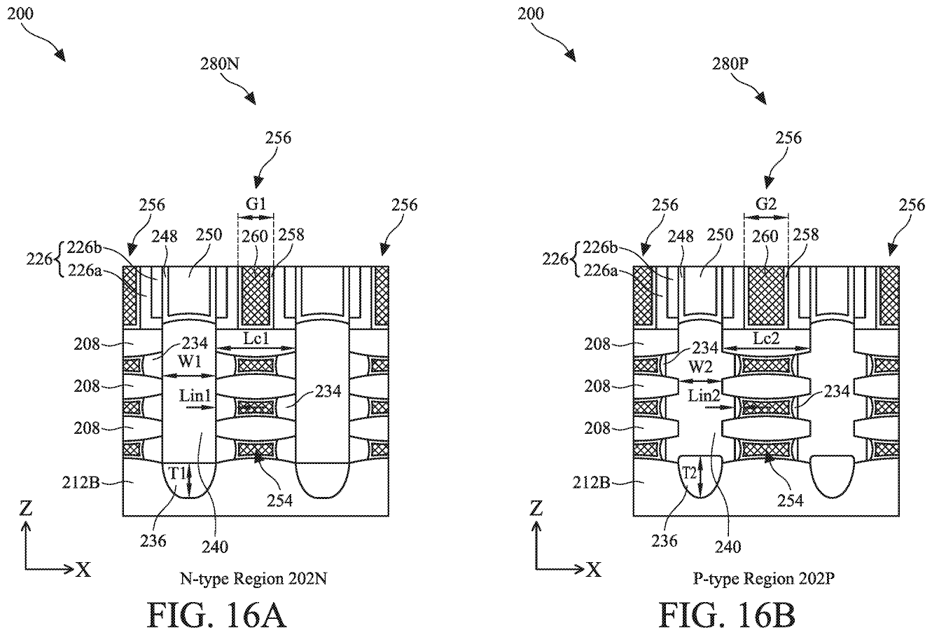

Referring to FIGS. 1 and 13A-16B, method 100 includes a block 118 where further processes are performed. Such further processes may include, for example, deposition of a contact etch stop layer (CESL) 248 over the workpiece 200 (shown in FIGS. 13A-13B), deposition of an interlayer dielectric (ILD) layer 250 over the CESL 248 (shown in FIGS. 13A-13B), removal of the dummy gate stack 220 (shown in FIGS. 14A-14B), selective removal of the sacrificial layers 206 in the channel region 212C to release the channel layers 208 as channel members (shown in FIGS. 15A-15B), and formation of a gate structure 256 over the channel region 212C (shown in FIGS. 16A-16B). Referring now to FIGS. 13A-13B, the CESL 248 is formed prior to forming the ILD layer 250. In some examples, the CESL 248 includes silicon nitride, silicon oxynitride, and/or other materials known in the art. The CESL 248 may be formed by ALD, plasma-enhanced chemical vapor deposition (PECVD) process and/or other suitable deposition processes. The ILD layer 250 is then deposited over the CESL 248. In some embodiments, the ILD layer 250 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 250 may be deposited by a PECVD process or other suitable deposition technique. In some embodiments, after formation of the ILD layer 250, the workpiece 200 may be annealed to improve integrity of the ILD layer 250. As shown in FIGS. 13A-13B, the CESL 248 is disposed directly on top surfaces of the doped epitaxial layer 240.

Referring to FIGS. 14A-14B, after the deposition of the CESL 248 and the ILD layer 250, the workpiece 200 may be planarized by a planarization process to expose the dummy gate stack 220. For example, the planarization process may include a chemical mechanical planarization (CMP) process. Exposure of the dummy gate stack 220 allows the removal of the dummy gate stack 220 and release of the channel layers 208. In some embodiments, the removal of the dummy gate stack 220 results in a gate trench 252 over the channel regions 212C. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. After the removal of the dummy gate stack 220, sidewalls of the channel layers 208 and the sacrificial layers 206 in the channel region 212C are exposed in the gate trench 252.

Referring to FIGS. 15A-15B, after the removal of the dummy gate stack 220, the method 100 may include operations to selectively remove the sacrificial layers 206 between the channel layers 208 in the channel region 212C. The selective removal of the sacrificial layers 206 releases the channel layers 208 to form channel members (also numbered as 208). The selective removal of the sacrificial layers 206 also leaves behind space 254 between channel members 208. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

Referring to FIGS. 16A-16B, the method 100 may include further operations to form the gate structure 256 to wrap around each of the channel members 208. In some embodiments, the gate structure 256 is formed within the gate trench 252 and into the space 254 left behind by the removal of the sacrificial layers 206. In this regard, the gate structure 256 wraps around each of the channel members 208. The gate structure 256 includes a gate dielectric layer 258 and a gate electrode layer 260 over the gate dielectric layer 258. In some embodiments, while not explicitly shown in the figures, the gate dielectric layer 258 includes an interfacial layer and a high-K gate dielectric layer. High-K dielectric materials, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-K gate dielectric layer may include hafnium oxide. Alternatively, the high-K gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material. The high-K gate dielectric layer may be formed by ALD, physical vapor deposition (PVD), CVD, oxidation, and/or other suitable methods.

The gate electrode layer 260 of the gate structure 256 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 260 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAIC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 260 may be formed by ALD, PVD. CVD, e-beam evaporation, or other suitable process. In various embodiments, a CMP process may be performed to remove excessive metal, thereby providing a substantially planar top surface of the gate structure 256. The gate structure 256 includes portions that interpose between channel members 208 in the channel region 212C.

Still referring to FIGS. 16A-16B, upon conclusion of the operations at block 118, multiple n-type transistors 280N (e.g., transistors T1-T4 in FIG. 2B) and multiple p-type transistors 280P (e.g., transistors T5-T6 in FIG. 2B) are substantially formed in the n-type region 202N and the p-type region 202P, respectively. Each of the transistors 280N and 280P includes channel members 208 that are vertically stacked along the Z direction. Each of the channel members 208 is wrapped around by the gate structure 256. The channel members 208 extend or are sandwiched between two source/drain features 240 along the X direction. Underneath the source/drain features 240 are the base epitaxial layers 236. The base epitaxial layer 236 may be an undoped epitaxial layer and exhibit high resistivity, thus providing a high resistance path from the source/drain features 246 to the substrate 202, such that the leakage current into the substrate 202 is suppressed. The gate structures 256 in the n-type transistors 280N have a gate width G1, and the gate structures 256 in the p-type transistors 280P have a gate width G2 that is larger than G1 (G2>G1). The channel members 208 in the n-type transistors 280N have a length Lc1, and the channel members 208 in the p-type transistors 280P have a length Lc2 that is larger than Lc1 (Lc2>Lc1). The source/drain features 240 in the n-type transistors 280N have a width W1, and the source/drain features 240 in the p-type transistors 280P have a width W2 that is smaller than W1 (W2<W1). The base epitaxial layers 236 in the n-type transistors 280N have a thickness T1, and the base epitaxial layers 236 in the p-type transistors 280P have a thickness T2 that is larger than T1 (T2>T1). The inner spacers 234 in the n-type transistors 280N have a thickness (or length) Lin1, and the inner spacers 234 in the p-type transistors 280P have a thickness (or length) Lin2 that is smaller than Lin1 (Lin2<Lin1). The thinned inner spacers 234 in the p-type transistors 280P allow the source/drain features 240 to have extending portions interleaving the channel members 208 in the p-type transistors 280P. The extending portions of the source/drain features 240 effectively reduce a lateral distance between the source/drain features 240 and an edge of the gate structure 256. The reduced lateral distance between the source/drain features 240 and an edge of the gate structure 256 mitigates the underlapped condition and offsets the negative impacts due to junction underlap, which boosts performance of p-type transistors without compromising performance of n-type transistors.

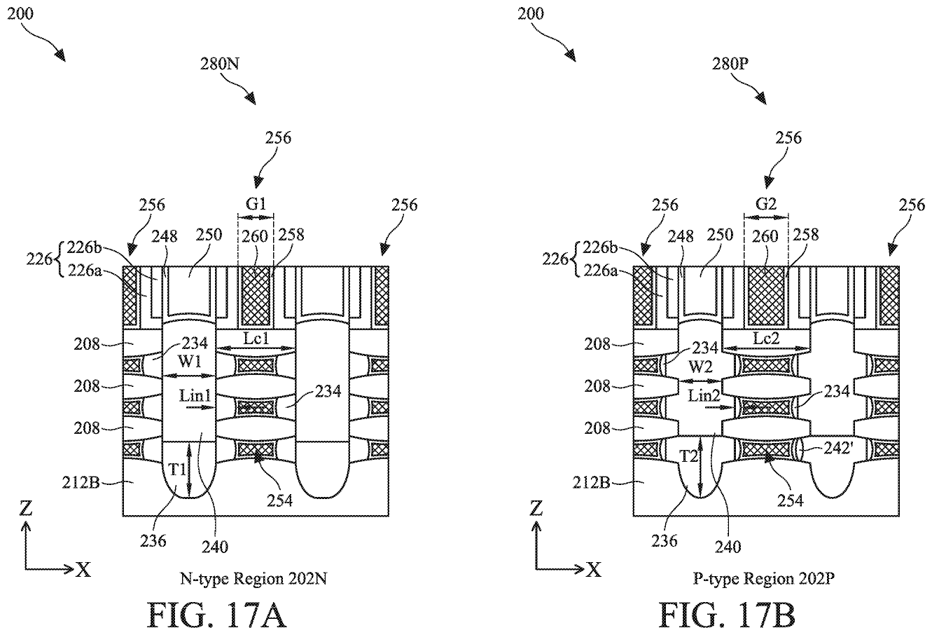

An alternative embodiment of the workpiece 200 is illustrated in FIGS. 17A-17B. Many aspects of the workpiece 200 in FIGS. 17A-17B and FIGS. 16A-16B are the same or similar. For clarity and case of reference, reference numerals for the same or similar features are repeated. One difference is that to form the depicted embodiment as in FIG. 17A-17B, block 110 in forming the base epitaxial layers 236 may be performed after blocks 112 and 114 in laterally recessing the inner spacers in the p-type region 202P. That is, during the epitaxial growth of the base epitaxial layers 236, the inner spacers 234 in the p-type region 202P are already thinned down. Since the epitaxial growth rate in the Z direction in the p-type region 202P may be larger than in the n-type region 202N due to the narrower opening of the source/drain trench 228 in the p-type region 202P, the base epitaxial layer 236 in the p-type region 202P may be thicker and reach a bottom surface of the bottommost channel member 208 and separates the source/drain features 240 from the bottommost inner spacers 234. The extending portion of the base epitaxial layer 236 in the p-type region 202P interleaves the bottommost channel member 208 and the top surface of the fin-shape base 212B. A void 242′ may also be sandwiched between a facet surface of the extending portion of the base epitaxial layer 236 and the bottommost inner spacer 234. The bottom surface of the source/drain features 240 in the p-type region 202P may be above the bottom surface of the bottommost channel member 208. As a comparison, the base epitaxial layers 236 in the n-type region 202N have a smaller thickness and may be below the bottom surface of the bottommost channel member 208. The source/drain features 240 in the n-type region 202N may still contact a top portion of the bottommost inner spacers 234.

Although not intended to be limiting, one or more embodiments of the present disclosure provide many benefits to a semiconductor device and the formation thereof. For example, embodiments of the present disclosure provide p-type transistors with inner spacers with reduced thickness compared to counterparts in n-type transistors. The thinned inner spacers reduce lateral distance between source/drain features and an edge of the gate structures. The reduced lateral distance mitigates the underlapped condition and offsets the negative impacts due to junction underlap, which boosts performance of p-type transistors without compromising performance of n-type transistors.

In one exemplary aspect, the present disclosure is directed to a method. The method includes forming an epitaxial stack of channel layers and sacrificial layers on a semiconductor substrate, the channel layers and the sacrificial layers having different material compositions and being alternatingly stacked in a vertical direction, patterning the epitaxial stack to form a first fin-shape structure protruding from a first region of the semiconductor substrate and a second fin-shape structure protruding from a second region of the semiconductor substrate, etching the first fin-shape structure to form a first source/drain recess in the first region, etching the second fin-shape structure to form a second source/drain recess in the second region, laterally recessing the sacrificial layers in the first fin-shape structure to form first inner spacer recesses, laterally recessing the sacrificial layers in the second fin-shape structure to form second inner spacer recesses, forming first inner spacers in the first inner spacer recesses, forming second inner spacers in the second inner spacer recesses, laterally recessing the second inner spacers to partially expose the second inner spacer recesses, after the laterally recessing of the second inner spacers the second inner spacers having a thickness less than the first inner spacers, forming a first source/drain feature in the first source/drain recess, and forming a second source/drain feature in the second source/drain recess. In some embodiments, the first region is an n-type transistor region, and the second region is a p-type transistor region. In some embodiments, a portion of the second source/drain feature extends into the second inner spacer recesses. In some embodiments, the method also includes depositing a first undoped layer in the first source/drain recess, and depositing a second undoped layer in the second source/drain recess. The first undoped layer is directly under the first source/drain feature, and the second undoped layer is directly under the second source/drain feature. In some embodiments, the depositing of the first undoped layer and the depositing of the second undoped layer are performed prior to the laterally recessing of the second inner spacers. In some embodiments, the depositing of the first undoped layer and the depositing of the second undoped layer are performed after the laterally recessing of the second inner spacers. In some embodiments, the second undoped layer has a thickness larger than the first undoped layer. In some embodiments, the method also includes prior to the laterally recessing of the second inner spacers, depositing a mask layer covering the first source/drain recess, such that the first inner spacers remain intact during the laterally recessing of the second inner spacers. In some embodiments, prior to the laterally recessing of the second inner spacers, the thickness of the second inner spacers is larger than the first inner spacers. In some embodiments, after the laterally recessing of the second inner spacers, the thickness of the second inner spacers is in a range between about 3 nm and about 6 nm.

In another exemplary aspect, the present disclosure is directed to a method. The method includes forming a fin-shape structure including a stack atop a base, the stack comprising a plurality of channel layers interleaved by a plurality of sacrificial layers, the base protruding from a substrate, the fin-shape structure comprising a channel region and a source/drain region, forming a dummy gate stack over the channel region of the fin-shape structure, depositing a gate spacer layer over the dummy gate stack, recessing the source/drain region to form a source/drain trench that exposes sidewalls of the channel layers and the sacrificial layers, selectively and partially recessing the sacrificial layers to form a plurality of inner spacer recesses, forming a plurality of inner spacers in the inner spacer recesses, depositing an undoped epitaxial layer in the source/drain trench, selectively and partially recessing the inner spacers to reduce a thickness of the inner spacers, depositing a doped epitaxial layer over the undoped epitaxial layer in the source/drain trench, the doped epitaxial layer being in contact with the channel layers, after the depositing of the doped epitaxial layer removing the dummy gate stack, releasing the channel layers in the channel region, and forming a gate structure wrapping around each of the channel layers. In some embodiments, after the depositing of the doped epitaxial layer, a portion of the doped epitaxial layer is vertically stacked between adjacent ones of the channel layers. In some embodiments, the reduced thickness of the inner spacers is in a range between about 3 nm and about 6 nm. In some embodiments, the depositing of the undoped epitaxial layer is performed prior to the selectively and partially recessing of the inner spacers. In some embodiments, the depositing of the undoped epitaxial layer is performed after the selectively and partially recessing of the inner spacers. In some embodiments, a portion of the undoped epitaxial layer is vertically stacked between a bottommost one of the channel layers and a top surface of the base. In some embodiments, the gate structure, the channel layers, and the doped epitaxial layer are portions of a p-type transistor.

In yet another exemplary aspect, the present disclosure is directed to a semiconductor device. The semiconductor device includes a plurality of first channel members suspended above a first region of a substrate, a plurality of first inner spacers interleaving the first channel members, a first gate structure wrapping around each of the first channel members, a first source/drain feature abutting the first channel members, a plurality of second channel members suspended above a second region of the substrate, a plurality of second inner spacers interleaving the second channel members, a second gate structure wrapping around each of the second channel members, and a second source/drain feature abutting the second channel members. A thickness of the second inner spacers is smaller than a thickness of the first inner spacers. In some embodiments, the first region is an n-type transistor region, and the second region is a p-type transistor region. In some embodiments, the second source/drain feature interleaves the second channel members.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an epitaxial stack of channel layers and sacrificial layers on a semiconductor substrate, the channel layers and the sacrificial layers having different material compositions and being alternatingly stacked in a vertical direction;
patterning the epitaxial stack to form a first fin-shape structure protruding from a first region of the semiconductor substrate and a second fin-shape structure protruding from a second region of the semiconductor substrate;
etching the first fin-shape structure to form a first source/drain recess in the first region;
etching the second fin-shape structure to form a second source/drain recess in the second region;
laterally recessing the sacrificial layers in the first fin-shape structure to form first inner spacer recesses;
laterally recessing the sacrificial layers in the second fin-shape structure to form second inner spacer recesses;
forming first inner spacers in the first inner spacer recesses;
forming second inner spacers in the second inner spacer recesses;
laterally recessing the second inner spacers to partially expose the second inner spacer recesses, wherein after the laterally recessing of the second inner spacers, the second inner spacers have a thickness less than the first inner spacers;
forming a first source/drain feature in the first source/drain recess; and
forming a second source/drain feature in the second source/drain recess.

2. The method of claim 1, wherein the first region is an n-type transistor region, and the second region is a p-type transistor region.

3. The method of claim 1, wherein a portion of the second source/drain feature extends into the second inner spacer recesses.

4. The method of claim 1, further comprising:
depositing a first undoped layer in the first source/drain recess; and
depositing a second undoped layer in the second source/drain recess, wherein the first undoped layer is directly under the first source/drain feature, and the second undoped layer is directly under the second source/drain feature.

5. The method of claim 4, wherein the depositing of the first undoped layer and the depositing of the second undoped layer are performed prior to the laterally recessing of the second inner spacers.

6. The method of claim 4, wherein the depositing of the first undoped layer and the depositing of the second undoped layer are performed after the laterally recessing of the second inner spacers.

7. The method of claim 4, wherein the second undoped layer has a thickness larger than the first undoped layer.

8. The method of claim 1, further comprising:
prior to the laterally recessing of the second inner spacers, depositing a mask layer covering the first source/drain recess, such that the first inner spacers remain intact during the laterally recessing of the second inner spacers.

9. The method of claim 1, wherein prior to the laterally recessing of the second inner spacers, the thickness of the second inner spacers is larger than the first inner spacers.

10. The method of claim 1, wherein after the laterally recessing of the second inner spacers, the thickness of the second inner spacers is in a range between about 3 nm and about 6 nm.

11. A method, comprising:
forming a fin-shape structure including a stack atop a base, the stack comprising a plurality of channel layers interleaved by a plurality of sacrificial layers, the base protruding from a substrate, the fin-shape structure comprising a channel region and a source/drain region;
forming a dummy gate stack over the channel region of the fin-shape structure;
depositing a gate spacer layer over the dummy gate stack;
recessing the source/drain region to form a source/drain trench that exposes sidewalls of the channel layers and the sacrificial layers;
selectively and partially recessing the sacrificial layers to form a plurality of inner spacer recesses;
forming a plurality of inner spacers in the inner spacer recesses;
depositing an undoped epitaxial layer in the source/drain trench;
selectively and partially recessing the inner spacers to reduce a thickness of the inner spacers;
depositing a doped epitaxial layer over the undoped epitaxial layer in the source/drain trench, the doped epitaxial layer being in contact with the channel layers;
after the depositing of the doped epitaxial layer, removing the dummy gate stack;
releasing the channel layers in the channel region; and
forming a gate structure wrapping around each of the channel layers.

12. The method of claim 11, wherein after the depositing of the doped epitaxial layer, a portion of the doped epitaxial layer is vertically stacked between adjacent ones of the channel layers.

13. The method of claim 11, wherein the reduced thickness of the inner spacers is in a range between about 3 nm and about 6 nm.

14. The method of claim 11, wherein the depositing of the undoped epitaxial layer is performed prior to the selectively and partially recessing of the inner spacers.

15. The method of claim 11, wherein the depositing of the undoped epitaxial layer is performed after the selectively and partially recessing of the inner spacers.

16. The method of claim 11, wherein a portion of the undoped epitaxial layer is vertically stacked between a bottommost one of the channel layers and a top surface of the base.

17. The method of claim 11, wherein the gate structure, the channel layers, and the doped epitaxial layer are portions of a p-type transistor.

18. A semiconductor device, comprising:
a plurality of first channel members suspended above a first region of a substrate;
a plurality of first inner spacers interleaving the first channel members;
a first gate structure wrapping around each of the first channel members;
a first source/drain feature abutting the first channel members;
a plurality of second channel members suspended above a second region of the substrate;
a plurality of second inner spacers interleaving the second channel members;
a second gate structure wrapping around each of the second channel members; and
a second source/drain feature abutting the second channel members,
wherein a thickness of the second inner spacers is smaller than a thickness of the first inner spacers.

19. The semiconductor device of claim 18, wherein the first region is an n-type transistor region, and the second region is a p-type transistor region.

20. The semiconductor device of claim 18, wherein the second source/drain feature interleaves the second channel members.
